(19) United States
(12) Patent Application Publication
(10) Pub. No.: US 2020/0168501 A1
(43) Pub. Date: May 28, 2020

(54) METHOD FOR PLANARIZING WAFER SURFACE

(71) Applicant: Shanghai Simgui Technology Co., Ltd., Shanghai (CN)

(72) Inventors: Xing WEI, Shanghai (CN); Nan GAO, Shanghai (CN); Meng CHEN, Shanghai (CN); Xin SU, Shanghai (CN); Hongtao XU, Shanghai (CN)

(73) Assignee: Shanghai Simgui Technology Co., Ltd., Shanghai (CN)

(21) Appl. No.: 16/597,685

(22) Filed: Oct. 9, 2019

(30) Foreign Application Priority Data
Nov. 27, 2018 (CN) 201811423858.3

(51) Int. Cl. H01L 21/762; H01L 21/3065

(52) U.S. Cl. CPC H01L 21/76254; H01L 21/3065

(57) ABSTRACT

A method for planarizing a wafer surface includes the following steps: providing a first wafer and a second wafer, oxidizing the first wafer to form an oxide layer on a surface of the first wafer, injecting a foaming ion to form a peeling layer in the first wafer, wherein an injection depth of the foaming ion is subject to the thickness of the oxide layer, bonding the first wafer and the second wafer to form a bonded wafer by using the oxide layer as an intermediate layer, raising a temperature to cause the bonded wafer to crack in the peeling layer, wherein a portion of the first wafer remaining on the surface of the oxide layer is a top silicon layer, and the oxide layer is an insulating buried layer; and annealing the bonded wafer.

### CROSS-REFERENCE TO RELATED APPLICATION

This application is based upon and claims priority to Chinese Patent Application No. 201811423858.3, filed on Nov. 27, 2018, the entire contents thereof are incorporated herein by reference.

### TECHNICAL FIELD

The present disclosure relates to the technical field of semiconductor manufacturing, and in particular, relates to a method for planarizing a wafer surface.

### BACKGROUND

SOI is a new generation silicon-base material that is extensively used, which gains more applications in low-voltage and low-power consumption circuits, micro-mechanical sensor, optoelectrical integration and the like fields. With respect to the SOI material, thickness uniformity of top-layer silicon is a critical parameter. This parameter greatly determines performance of a device.

In an SOI process, planarization of the top-layer silicon is generally practiced by a chemical mechanical polishing (CMP) process. With a stricter requirement on uniformity of the top-layer silicon, the CMP process fails to accommodate relevant process requirements.

### SUMMARY

The present disclosure provides a method for planarizing a wafer surface.

The method includes the following steps: providing a wafer, the wafer including an insulating buried layer and a top silicon layer disposed on a surface of the insulating buried layer, the top silicon layer having a thickness which is greater at an edge than at a center; and annealing the wafer in a mixed gas of hydrogen and an inert gas, wherein the annealing promotes reconstruction of silicon atoms on the wafer surface such that planarization of top-layer silicon is promoted, and a reconstruction rate is higher at the edge than at the center such that thickness uniformity of the top layer silicon is improved.

The present invention further provides a method for planarizing a wafer surface. The method includes the following steps: providing a wafer, the wafer including an insulating buried layer and a top silicon layer disposed on a surface of the insulating buried layer, the top silicon layer having a thickness which is greater at an edge than at a center; and etching the top silicon layer with a mixed gas of hydrogen and HCl, wherein the etching process has an etch rate which is higher at the edge that at the center such that thickness uniformity of the top silicon layer is improved.

### BRIEF DESCRIPTION OF THE DRAWINGS

FIG. 1 is a schematic diagram of steps of a method for planarizing a wafer surface, according to an embodiment of the present invention;

FIG. 2A shows a process schematic diagram, according to an embodiment of the present invention;

FIG. 2B shows a process schematic diagram, according to an embodiment of the present invention;

FIG. 2C shows a process schematic diagram, according to an embodiment of the present invention;

FIG. 2D shows a process schematic diagram, according to an embodiment of the present invention;

FIG. 2E shows a process schematic diagram, according to an embodiment of the present invention;

FIG. 3A shows a process schematic diagram, according to an embodiment of the present invention; and

FIG. 3B shows a process schematic diagram, according to an embodiment of the present invention.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the disclosure as recited in the appended claims.

The terminology used in the present disclosure is for the purpose of describing particular embodiments only and is not intended to limit the present disclosure. As used in the present disclosure and the appended claims, the singular forms “a,” “an,” and “the” are intended to include the plural forms as well, unless the context clearly indicates otherwise. It shall also be understood that the term “and/or” used herein is intended to signify and include any or all possible combinations of one or more of the associated listed items.

It shall be understood that, although the terms “first,” “second,” “third,” etc. may be used herein to describe various information, the information should not be limited by these terms. These terms are only used to distinguish one category of information from another. For example, without departing from the scope of the present disclosure, first information may be termed as second information; and similarly, second information may also be termed as first information. As used herein, the term “if” may be understood to mean “when” or “upon” or “in response to a judgment” depending on the context.

Hereinafter, specific embodiments of a method for planarizing a wafer surface according to the present invention are described in detail with reference to the accompanying drawings.

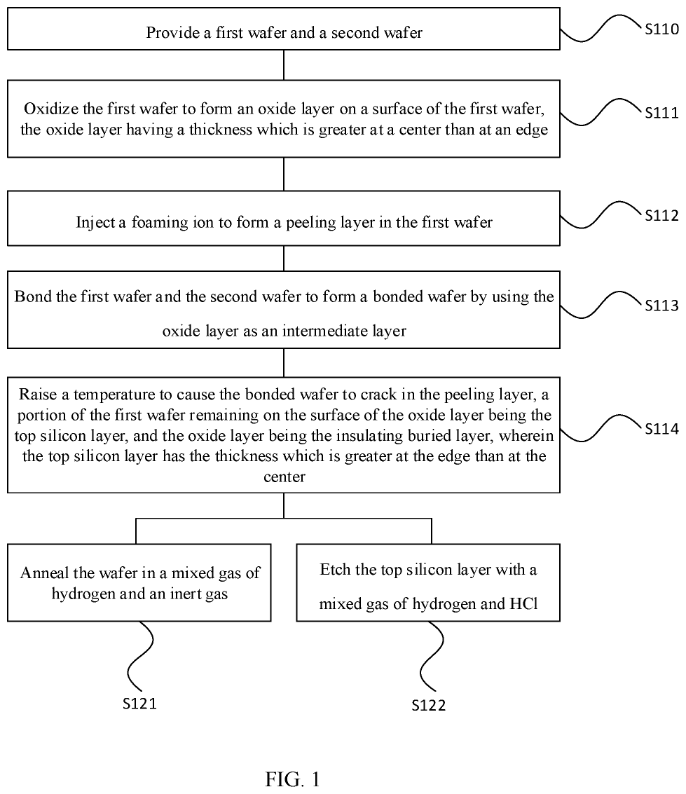

FIG. 1 is a schematic diagram of steps of a method for planarizing a wafer surface according to an embodiment of the present invention. The method includes: step S110: providing a first wafer and a second wafer; step S111: oxidizing the first wafer to form an oxide layer on a surface of the first wafer, the oxide layer having a thickness which is greater at a center than at an edge; step S112: injecting a foaming ion to form a peeling layer in the first wafer; step S113: bonding the first wafer and the second wafer to form a bonded wafer by using the oxide layer as an intermediate layer; step S114: raising a temperature to cause the bonded wafer to crack in the peeling layer, a portion of the first wafer remaining on the surface of the oxide layer being the top silicon layer, and the oxide layer being the insulating buried layer, wherein the top silicon layer has the thickness which is greater at the edge than at the center; step S121 annealing the wafer in a mixed gas of hydrogen and an inert gas; and step S122: etching the top silicon layer with a mixed gas of hydrogen and HCl.

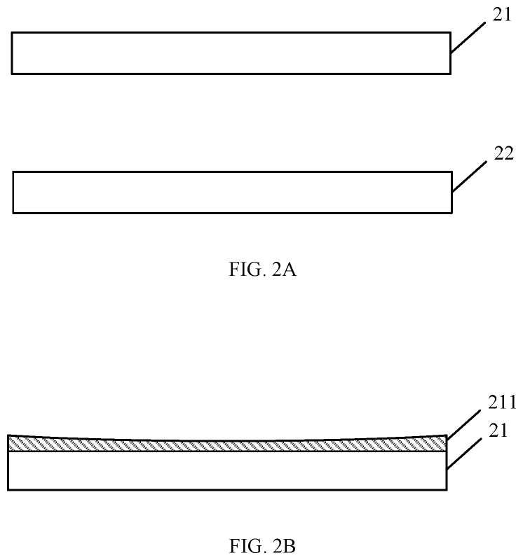

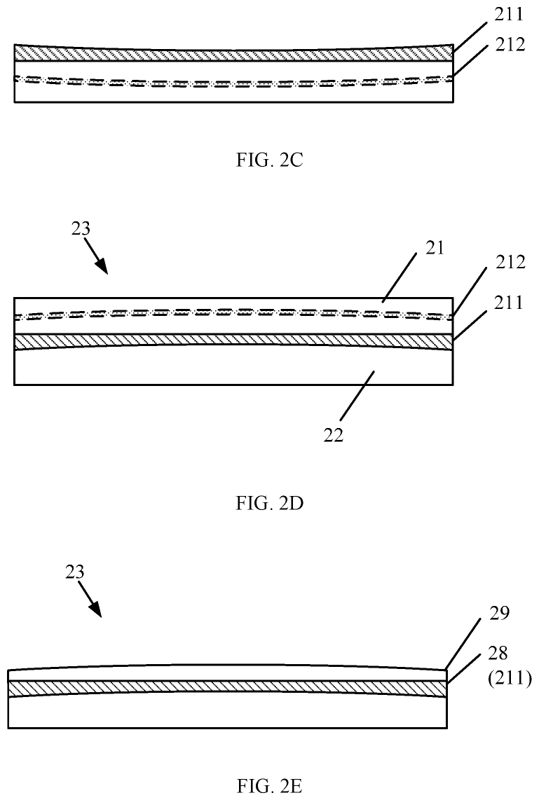

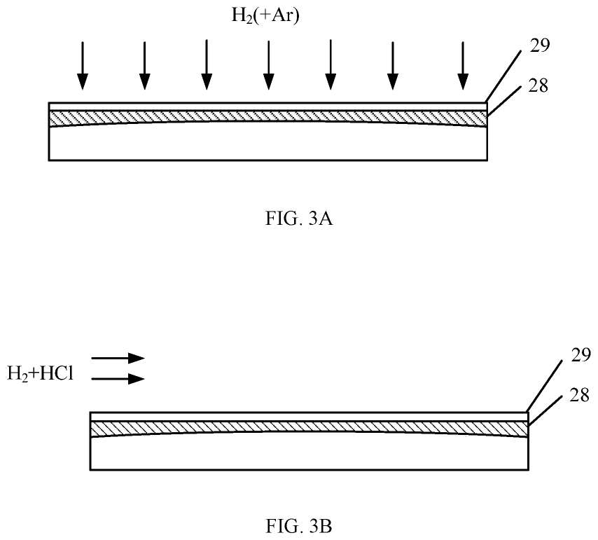

FIG. 2A to FIG. 2E, and FIG. 3A to FIG. 3B are process schematic diagrams of the above steps.

As illustrated in FIG. 2A, referring to step S110, a first wafer 21 and a second wafer 22 are provided. The first wafer 21 is used for a subsequent peeling process, wherein the surface thereof to be peeled is a monocrystal material. The second wafer 22 is used as a support substrate for bonding, wherein materials thereof may include monocrystal silicon, sapphire, silicon carbide and any other commonly used semiconductor substrate material.

As illustrated in FIG. 2B, referring to step S111, the first wafer 21 is oxidized to form an oxide layer 211 on a surface of the first wafer, wherein the oxide layer 211 has a thickness which is greater at a center than at an edge. The oxidation may be carried out by a dry oxygen or wet oxygen oxidation method, and a material of the formed oxide layer 211 is silica, and the formed oxide layer 211 has a thickness which is less than 500 nm. Studies reveal that a thickness feature exhibited by the oxide layer 211 formed by oxidation is that the thickness is greater at the center that at the edge, and thus central symmetric distribution is exhibited. This is determined by inherited characteristics of the oxidation process and is hard to be modified by adjusting process parameters.

As illustrated in FIG. 2C, referring to step S112, a foaming ion is injected to form a peeling layer 212 in the first wafer 21. The foaming ion is selected from the group consisting of hydrogen, helium and a mixture gas of hydrogen and helium, an injection energy is less than 100 keV, and an injection amount is in the range of 1×10¹⁶ cm⁻² to 6×10¹⁶ cm⁻².

As illustrated in FIG. 2D, referring to step S113, the first wafer 21 and the second wafer 22 are bonded to form a bonded wafer 23 by using the oxide layer 211 as an intermediate layer.

As illustrated in FIG. 2E, referring to step S114, a temperature is raised to cause the bonded wafer 23 to crack in the peeling layer 212, wherein a portion of the first wafer remaining on the surface of the oxide layer 211 is the top silicon layer 29, and the oxide layer 211 is the insulating buried layer 28. Cracking of the bonded wafer 23 in the peeling layer 212 is practiced at a temperature in the range of from 300° C. to 600° C. and at a duration of from 10 min to 60 min. Since an injection depth of the foaming ion is subject to the thickness of the oxide layer 211, the greater the thickness of the oxide layer, the more apparent the blocking effect against the injected ion. As a result, the top silicon layer 29 after peeling has a thickness which is greater at the edge that at the center, and thus central symmetric distribution is exhibited.

After steps S110 to S114 are performed, the bonded wafer 23 is obtained, which includes the top silicon layer 29 and the insulating buried layer 28. Since the thickness of the top silicon layer 29 exhibits the central symmetric distribution, distribution of the thickness may be modified by a surface treatment process, such that the uniform distribution is more uniform. The above method for acquiring the wafer is a method according to a specific embodiment. In other specific embodiments, any method which may cause the thickness of the top silicon layer 29 to exhibit central symmetric distribution, when being employed, may possibly achieve the same or similar structure.

With respect to the wafer in which the thickness of the top silicon layer exhibits central symmetric distribution, it is necessary to propose a process to modify such distribution of the thickness to make the thickness distribution more uniform. Step S121 and step S122 hereinafter are two parallel steps, which both modify the distribution of the thickness by virtue of the characteristics of the surface treatment process. These two steps may be alternatively performed to acquire the top silicon layer with more uniform thickness distribution.

As illustrated in FIG. 3A, referring to step S121, the wafer 23 is annealed at an hydrogen atmosphere or in a mixed gas of hydrogen and an inert gas. The inert gas could include argon. The annealing may promote reconstruction of silicon atoms on the surface, such that planarization of the top silicon layer 29 is promoted. In addition, the construction rate at the edge is higher than that at the center, such that the thickness uniformity of the top silicon layer 29 is improved. In a specific embodiment in which the annealing is carried out at a hydrogen atmosphere, an annealing temperature is in the range of from 1000° C. to 1200° C. and an annealing duration is in the range of from 30 min to 120 min. In a specific embodiment in which the annealing is carried out at a mixed gas atmosphere of hydrogen and an inert gas, an annealing temperature is in the range of from 950° C. to 1200° C. and an annealing duration is in the range of from 30 min to 120 min. Since the top silicon layer 29 has a small target thickness, which is generally less than 200 nm, even less than 20 nm, the chemical mechanical polishing fails to accommodate the requirement on flatness. The method of promoting silicon atom reconstruction on the surface by using hydrogen may accurately control surface flatness relative to the polishing process, and thus the process requirement is satisfied. Studies reveal that under the same annealing process conditions at the edge and at the center, the reconstruction rate at the edge of the wafer is slightly higher than that at the center, and thus central symmetric distribution is exhibited, which may rightly offset the central symmetric distribution exhibited by the thickness of the top silicon layer 29. In this way, the top silicon layer 29 with a more uniform thickness is obtained.

As illustrated in FIG. 3B, referring to step S122, a surface of the top silicon layer is etched with a mixed gas of hydrogen and HCl, wherein the mixed gas is injected from a side of the wafer 23, and a flow rate the mixed gas in an edge region is less than a flow rate of the mixed gas at a central region. In an embodiment of an etching effect, the top silicon layer 29 is subjected to hydrogen baking before etching to remove a natural oxide layer on the surface thereof. Typically, such surface treatment is carried out at a temperature greater 1100° C. and at a duration over 40 s, to ensure subsequent etching of the silicon by HCl. In this specific embodiment, the step of etching is performed at a temperature greater than 1050° C., and in the step of etching, a volume fraction of HCl in the mixed gas is less than 1%, and the flow rate of the mixed gas is in the range of from 60 L/min to 120 L/min. In an embodiment of an etching effect, an etching removal amount of the top silicon layer 29 is greater than 80 nm. Since the top silicon layer 29 has a small target thickness, which is generally less than 200 nm, even less than 20 nm, the chemical mechanical polishing fails to accommodate the requirement on flatness. The HCl etching method may accurately control surface flatness relative to the polishing process, and thus the process requirement is satisfied. Studies reveal that under the same etching process conditions at the edge and at the center, the etch rate at the edge of the wafer is slightly higher than that at the center, and thus central symmetric distribution is exhibited, which may rightly offset the central symmetric distribution exhibited by the thickness of the top silicon layer 29. In this way, the top silicon layer 29 with a more uniform thickness is obtained.

For example, the wafer is formed by the following steps: providing a first wafer and a second wafer; oxidizing the first wafer to form an oxide layer on a surface of the first wafer, the oxide layer having a thickness which is greater at a center than at an edge; injecting a foaming ion to form a peeling layer in the first wafer; bonding the first wafer and the second wafer to form a bonded wafer by using the oxide layer as an intermediate layer; and raising a temperature to cause the bonded wafer to crack in the peeling layer, a portion of the first wafer remaining on the surface of the oxide layer being the top silicon layer, and the oxide layer being the insulating buried layer, wherein an injection depth of the foaming ion is subject to the thickness of the oxide layer, and thus the top silicon layer has the thickness which is greater at the edge than at the center. The foaming ion is one selected form the group consisting of hydrogen, helium and a mixed gas of hydrogen and helium.

For example, the annealing is carried out at a hydrogen atmosphere at an annealing temperature of from 1000° C. to 1200° C. and at an annealing duration of from 30 min to 120 min.

For example, the annealing is carried out at the mixed gas of hydrogen and the inert gas at an annealing temperature of from 95° C. to 1200° C. and at an annealing duration of from 30 min to 150 min.

For example, a temperature in the step of etching is greater than 1050° C.

For example, in the step of etching, a volume fraction of HCl in the mixed gas is less than 1%.

For example, in the step of etching, the flow rate of the mixed gas is in the range of from 60 L/min to 120 L/min.

Studies reveal that under the same hydrogen-containing etching process or HCL-containing etching process conditions at the edge and at the center, a thickness change rate at the edge of the wafer is slightly higher than that at the center, and thus central symmetric distribution is exhibited, which may rightly offset the central symmetric distribution exhibited by the thickness of the top silicon layer. In this way, the top silicon layer with a more uniform thickness is obtained. In the above processes, thickness distribution is improved by virtue of the characteristics of the surface treatment process.

Described above are embodiments of the present disclosure. It should be noted that persons of ordinary skill in the art may derive other improvements or polishments without departing from the principles of the present invention. Such improvements and polishments shall be deemed as falling within the protection scope of the present invention.

What is claimed is:

1. A method for planarizing a wafer surface comprising:
providing a first wafer and a second wafer;
oxidizing the first wafer to form an oxide layer on a surface of the first wafer, wherein the oxide layer has a thickness which is greater at a center than at an edge;
injecting a foaming ion to form a peeling layer in the first wafer, wherein an injection depth of the foaming ion is subject to the thickness of the oxide layer;
bonding the first wafer and the second wafer to form a bonded wafer by using the oxide layer as an intermediate layer;
raising a temperature to cause the bonded wafer to crack in the peeling layer, wherein a portion of the first wafer remaining on the surface of the oxide layer is a top silicon layer, and the oxide layer is an insulating buried layer, wherein the top silicon layer has the thickness which is greater at the edge than at the center; and
annealing the bonded wafer.

2. The method according to claim 1, wherein the foaming ion is either hydrogen, helium or a mixed gas of hydrogen and helium.

3. The method according to claim 1, wherein annealing the bonded wafer comprises using a hydrogen atmosphere.

4. The method according to claim 1, wherein annealing the bonded wafer comprises using a mixed gas of hydrogen and an inert gas.

5. The method according to claim 1, wherein annealing the bonded wafer comprises promoting reconstruction of silicon atoms on the wafer surface such that planarization of top-layer silicon is promoted, and a reconstruction rate is higher at the edge than at the center such that there is thickness uniformity at the top silicon layer.

6. A method for planarizing a wafer surface comprising:
providing a first wafer and a second wafer;
oxidizing the first wafer to form an oxide layer on a surface of the first wafer, wherein the oxide layer has a thickness which is greater at a center than at an edge;
injecting a foaming ion to form a peeling layer in the first wafer, wherein an injection depth of the foaming ion is subject to the thickness of the oxide layer;
bonding the first wafer and the second wafer to form a bonded wafer by using the oxide layer as an intermediate layer;
raising a temperature to cause the bonded wafer to crack in the peeling layer, wherein a portion of the first wafer remaining on the surface of the oxide layer is a top silicon layer, and the oxide layer is an insulating buried layer, wherein the top silicon layer has the thickness which is greater at the edge than at the center; and
etching the top silicon layer with a mixed gas of hydrogen and HCl.

7. The method according to claim 6, wherein the foaming ion is either hydrogen, helium, or a mixed gas of hydrogen and helium.

8. The method according to claim 6, wherein raising a temperature to cause the bonded wafer to crack in the peeling layer comprises raising the temperature above 1050° C.

9. The method according to claim 6, wherein a volume fraction of HCl in the mixed gas of less than 1%.

10. The method according to claim 6, wherein in the step of etching, a flow rate of the mixed gas is in the range between 60 L/min and 120 L/min.

11. The method according to claim 6, wherein etching the top silicon layer with a mixed gas of hydrogen and HCl comprises an etch rate which is higher at the edge than at the center such that there is thickness uniformity for the top silicon layer.

12. A method for planarizing a wafer surface comprising:
providing a wafer, the wafer comprising an insulating buried layer and a top silicon layer disposed on a surface of the insulating buried layer, the top silicon layer having a thickness which is greater at an edge than at a center; and
annealing the wafer in a mixed gas of hydrogen and an inert gas, wherein the annealing promotes reconstruction of silicon atoms on the wafer surface such that planarization of top-layer silicon is promoted, and a reconstruction rate is higher at the edge than at the center such that there is thickness uniformity at the top silicon layer.

13. The method according to claim 12, wherein the wafer is formed by:
providing a first wafer and a second wafer;
oxidizing the first wafer to form an oxide layer on a surface of the first wafer, wherein the oxide layer has a thickness which is greater at a center than at an edge;
injecting a foaming ion to form a peeling layer in the first wafer, wherein an injection depth of the foaming ion is subject to the thickness of the oxide layer, and thus the top silicon layer has the thickness which is greater at the edge than at the center;
bonding the first wafer and the second wafer to form a bonded wafer by using the oxide layer as an intermediate layer; and
raising a temperature to cause the bonded wafer to crack in the peeling layer, wherein a portion of the first wafer remaining on the surface of the oxide layer is the top silicon layer, and the oxide layer is the insulating buried layer.

14. The method according to claim 13, wherein annealing the bonded wafer comprises using a hydrogen atmosphere.

15. The method according to claim 13, wherein annealing the bonded wafer comprises using a mixed gas of hydrogen and an inert gas.

16. The method according to claim 13, wherein annealing the bonded wafer comprises promoting reconstruction of silicon atoms on the wafer surface such that planarization of top-layer silicon is promoted, and a reconstruction rate is higher at the edge than at the center such that there is thickness uniformity at the top silicon layer.
